(19) United States
(12) Patent Application Publication
(10) Pub. No.: US 2007/0029649 A1
(43) Pub. Date: Feb. 8, 2007

(54) Plastic lead frame with snap-together circuitry

(75) Inventor: Stephen R. Shiffer, Xenia, OH (US)

Correspondence Address: Kris T. Fredrick;Honeywell International Inc., 101 Columbia Rd., P.O. Box 2245, Morristown, NJ, 07962, US

(73) Assignee: Honeywell International Inc.

(21) Appl. No.: 11/200,350

(22) Filed: Aug. 8, 2005

(51) Int. Cl. H01L 23/495

(52) U.S. Cl. 257/666

(57) ABSTRACT

A plastic lead frame with snap-together electrical connectors, electrical component system, and method using plastic-injection, plating, and known photolithography techniques is disclosed. The plastic lead frame and electrical component system operates with an integrated circuit, which functions as a sensor, such as a Hall-Effect sensor. The snap-together connectors allow interference joints to become electrical connections. Using a plastic lead frame, simple sensors may be electrically connected to the integrated circuit without a metal lead frame.

### TECHNICAL FIELD

Embodiments are generally related to the manufacture of integrated circuit (IC) sensors, particularly plastic lead frames, electrical component systems, and methods. Embodiments are further related to snap-together electrical connections used with plastic lead frames. Embodiments are additionally related to plastic injection molding, plating, and photolithography.

### BACKGROUND

Lead frames serve as the ‘backbone’ of integrated circuit components throughout the manufacturing process. Current implementations of lead frame systems employ stamped or etched metal. The cost of raw metallic alloys, processing, and assembly are having a dramatically negative impact in the high-volume sensor market and elsewhere. Additional burden is placed on manufacturers due to lead frame components that do not easily fit together in various configurations.

Plastic lead frames provide an alternative to traditional stamped or etched metal lead frames, in that they are cheaper to manufacture, require less time to produce, and offer a higher degree of precision which can be more readily tailored to individual customers' needs. Circuit layout modifications can now be accomplished within one day using this new innovation, compared to conventional stamped metal lead frames, which can take up to several weeks or even months to complete. In addition, this precision processing can be used to create plastic lead frames that employ snap-together designs.

The plastic lead frames are manufactured by initially heating raw plastic materials (typically in a granular or pelletized form) until liquefied. These raw plastic materials may comprise recycled plastic components, such as inoperative plastic lead frames, thus supporting environmental initiatives. Using a plastic-injection molding machine, the liquefied plastic is infused into a pressurized mold of the customer-specified lead frame. Once cooled until hardened, the plastic lead frame is then removed from the mold and ready for the remaining steps in the manufacturing process.

After the plastic lead frame is formed, it is plated with a chemical substance, often metallic in nature, to insure effective bonding and conductivity. Finally, the desired circuit layout is projected onto the plastic lead frame using photolithographic techniques well-established in the art, and the integrated circuit is inspected for quality assurance before implementation.

### BRIEF SUMMARY

The following summary is provided to facilitate an understanding of some of the innovative features unique to the present invention and is not intended to be a full description. A full appreciation of the various aspects of the invention can be gained by taking the entire specification, claims, drawings, and abstract as a whole.

According to aspects illustrated herein, there is provided a plastic lead frame and electrical component system comprising an integrated circuit functioning as a sensor and a plastic lead frame including snap-together electrical connections formed thereon and operating as a linkage between said sensor and at least one external electrical power source.

In accordance with another feature, there is provided an electrical component system comprising an integrated circuit functioning as a sensor and a plastic-injected lead frame wherein said plastic lead frame includes at least one electrically conductive snap-together connector configured as an electrical linkage between said sensor and external electronic components including a power source.

Other disclosed features of the embodiments include a method of employing plastic lead frames to mount and electrically connect electrical devices, comprising heating raw plastic materials in a granular form until said materials liquefy, injecting the liquefied plastic into a pressurized mold in the shape of a customer-specified plastic lead frame including at least one electrically conductive snap-together connector, cooling said liquefied plastic until said plastic lead frame is hardened and formed, plating said plastic lead frame with a chemical substance, projecting at least one circuit layout onto said plastic lead frame using known photolithographic techniques, connecting said plastic lead frame to said electrical devices by snapping-together said plastic lead frame into a specified configuration, and removing said plastic lead frame from said electrical devices by snapping-apart said plastic lead frame from a specified configuration, thus facilitating serviceability and/or replacement.

### BRIEF DESCRIPTION OF THE DRAWINGS

The accompanying figures, in which like reference numerals refer to identical or functionally-similar elements throughout the separate views and which are incorporated in and form a part of the specification, further illustrate the present invention and, together with the detailed description of the invention, serve to explain the principles of the present invention.

FIG. 1 illustrates a plan view of a plastic lead frame connected to an integrated circuit functioning as a sensor which can be implemented in accordance with a preferred embodiment;

FIG. 2 illustrates varied configurations of a plastic lead frame and electrical component system comprising an integrated circuit functioning as a sensor and a plastic lead frame including snap-together electrical connections which can be adapted for use in accordance with a preferred embodiment;

FIG. 3 depicts a flow chart illustrating the manufacturing process employed in producing a plastic lead frame in conjunction with an integrated circuit;

FIG. 4 illustrates a typical plastic-injection molding machine used to manufacture a plastic lead frame;

### DETAILED DESCRIPTION OF THE INVENTION

The particular values and configurations discussed in these non-limiting examples can be varied and are cited merely to illustrate at least one embodiment of the present invention and are not intended to limit the scope of the invention.

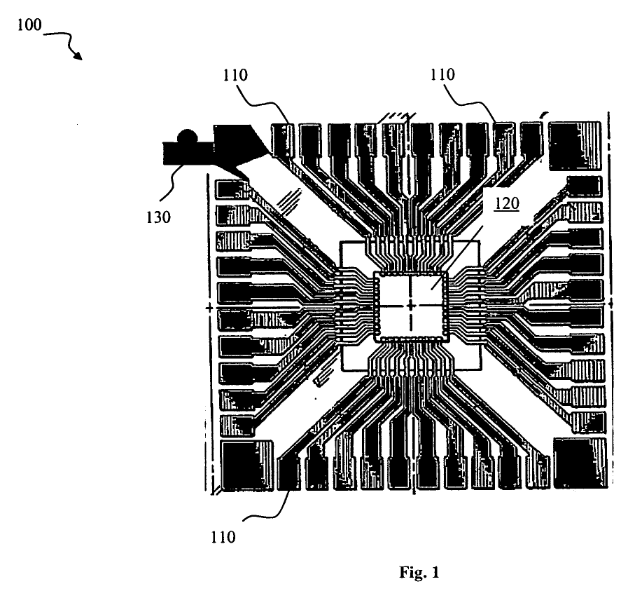

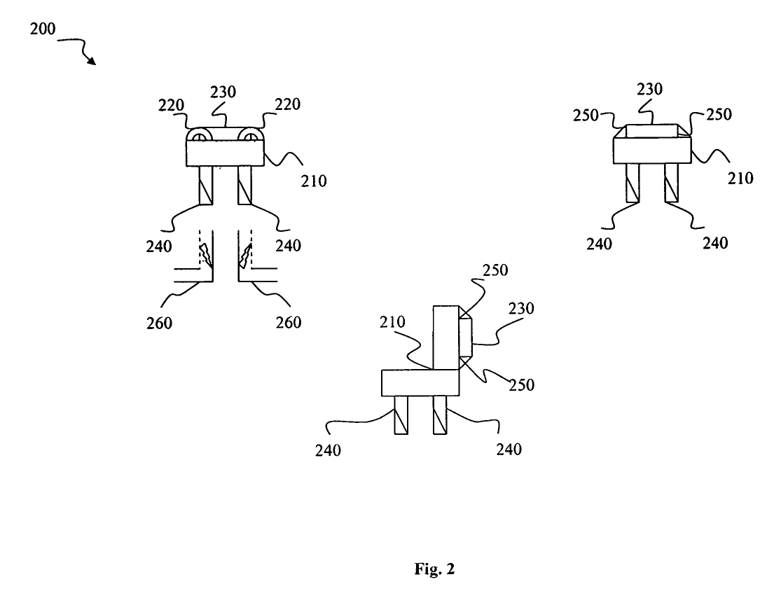

Referring to FIG. 1, a depiction 100 illustrating a plastic lead frame 110 connected to an integrated circuit 120 functioning as a sensor which can be implemented in accordance with a preferred embodiment is shown. The plastic lead frame 110 was engineered to customer-driven specifications. Note that in FIGS. 1 and 2 identical or similar parts or elements are generally indicated by identical reference numerals.

Further illustrated by FIG. 1 is a plastic injection point 130, which can be adapted for use in accordance with a preferred embodiment. The plastic injection point 130 facilitates the formation of the plastic lead frame 110, by providing an external fill location, whereby the liquefied plastic materials are poured and/or injected into the desired plastic lead frame mold and allowed to harden. The placement of the plastic injection point 130 as depicted in FIG. 1 is illustrative only and may be modified or varied, depending upon design considerations, and could include the implementation of multiple plastic injection points 130. Additionally, the geometric shape of the plastic injection point 130 can also be modified or varied.

Referring to FIG. 2, a depiction 200 illustrating configurations of a plastic lead frame and electrical component system comprising an integrated circuit 230 functioning as a sensor and a plastic lead frame 210 including snap-together electrical connections which can be adapted for use in accordance with a preferred embodiment is shown.

A plastic lead frame 210 is shown operatively connected to an integrated circuit 230 functioning as a sensor (e.g., Hall-effect, pressure) in a typical configuration with the integrated circuit 230 secured to the plastic lead frame 210 by wire bonding 220. Also depicted are two electrically conductive, plastic terminals 240, which can be snapped together and apart with another electrical component 260. This function facilitates serviceability and/or replacement.

Another illustration depicts a plastic lead frame 210 operatively connected to an integrated circuit 230 functioning as a sensor in a typical configuration. However, in this illustration, the integrated circuit 230 is secured to the plastic lead frame 210 by an adhesive substance 250. Also depicted are two electrically conductive, plastic terminals 240. Again, this plastic lead frame 210 can also be snapped together and apart to illustrate an embodiment.

Again referring to FIG. 2, a plastic lead frame 210 is shown operatively connected to an integrated circuit 230 secured to the plastic lead frame 210 by an adhesive substance 250. However, this configuration shows the plastic lead frame 210 rotated approximately 90 degrees to accommodate a customer-specified design. Also depicted are two electrically conductive, plastic terminals 240. By using plastic lead frames 210 with snap-together capabilities, the customer can have added flexibility at a reduced manufacturing cost.

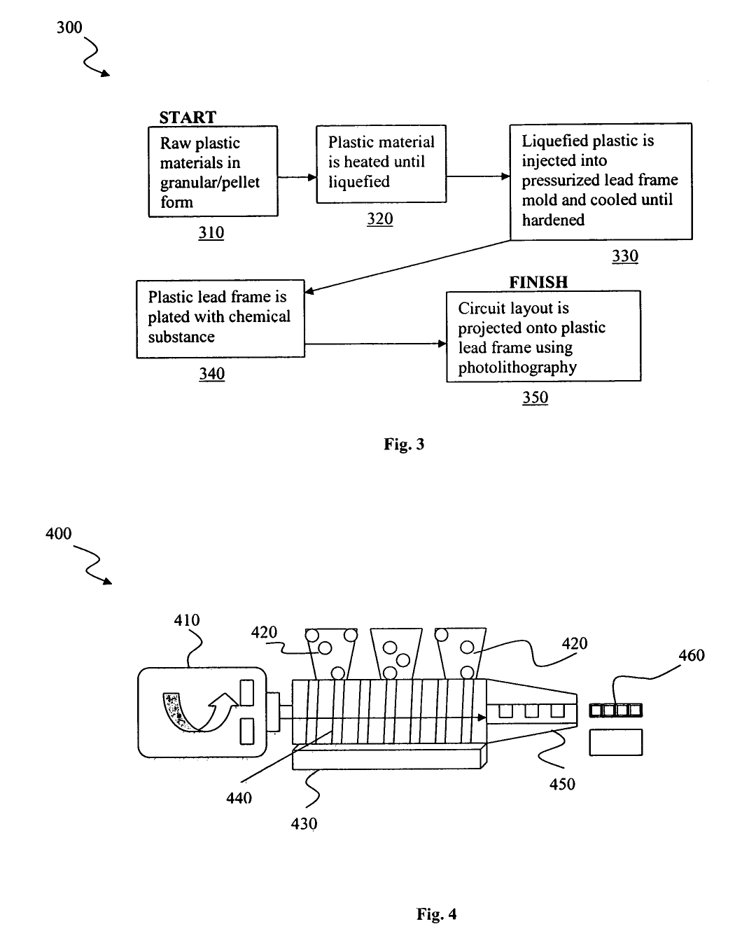

Referring to FIG. 3, a flow chart 300 illustrating the manufacturing process employed in producing a plastic lead frame in conjunction with an integrated circuit is shown.

The first step in the production of the plastic lead frame utilizes raw or recycled plastic (polymer) materials in a granular or pellet form as shown in block 310. Granular or pelletized materials are used in part because of the ability to precisely control the flow of injection and also to facilitate consistency among the melted plastic.

Once the granular or pelletized raw materials are poured into the plastic-injection molding machine, the material is heated at a high temperature (typically 400-500 degrees Fahrenheit) until liquefied as shown in block 320. The liquefied plastic material is then injected into a highly pressurized lead frame mold and is allowed to cool until the plastic lead frame is solidified as shown in block 330. Once hardened, the plastic lead frame is removed from the mold and prepared for additional processing. Prototypes of plastic lead frames can be manufactured-using this process within one day.

The newly molded plastic lead frame must then be plated with a conductive material such as Nickel, Gold, Copper, and/or Palladium as shown in block 340. This plating process can be implemented in a variety of configurations, such as spot, selective, and complete plating to accommodate customer needs. Both electrolytic and non-electrolytic plating methods can be used either in combination or individually to complete this step.

Lastly, the desired circuit layout is projected onto the plastic lead frame and circuit using photolithography as shown in block 350. A “photomask” is a plate with an emulsion of metal film with the desired circuit layout located on one side. The mask is aligned with the plastic lead frame and circuit, so that the desired pattern can be transferred onto the surface. Once the photomask has been accurately aligned with the desired pattern on the surface of the plastic lead frame and circuit, a previously deposited photoresist is exposed through the pattern on the photomask with a high intensity ultraviolet light.

Referring to FIG. 4, a depiction 400 illustrating a typical plastic-injection molding machine is shown. The plastic-injection machine 400 is actuated by a motor 410, which turns an auger 440 that mixes the raw plastic materials (in a granular or pellet form) which were fed into the plastic-injection machine by multiple hoppers 420. While in the plastic-injection machine, the raw plastic materials are liquefied by a heater 430 and subsequently injected into a plastic lead frame mold 450. Once cooled, the finished plastic lead frames 460 are ejected from the machine and ready for additional processing as described in FIG. 3.

It will be appreciated that various of the above disclosed and other features and functions, or alternatives thereof, may be desirably combined into many other different systems or applications. Various presently unforeseen or unanticipated alternatives, modifications, variations, or improvements therein may be subsequently made by those skilled in the art which are also intended to be encompassed by the following claims.

The embodiments of the invention in which an exclusive property or right is claimed are defined as follows.

Having thus described the invention what is claimed is:

1. A plastic lead frame and electrical component system comprising:
an integrated circuit functioning as a sensor; and
a plastic lead frame including snap-together electrical connections formed thereon and operating as a linkage between said sensor and at least one external electrical power source.

2. The plastic lead frame and electrical component system of claim 1, wherein said plastic lead frame includes at least one electrically conductive snap-together connector for linking at least part of said sensor to the at least one external power source.

3. The plastic lead frame and electrical component system of claim 1, wherein said integrated circuit is configured as an automotive gear tooth sensor and wherein said plastic lead frame includes at least one electrically conductive snap-together connector for linking at least part of said sensor to the at least one external power source.

4. The plastic lead frame and electrical component system of claim 1, wherein said integrated circuit is configured as a pressure sensor and wherein said plastic lead frame includes at least one electrically conductive snap-together connector for linking at least part of said sensor to the at least one external power source.

5. The plastic lead frame and electrical component system of claim 1, wherein said integrated circuit is configured as a Hall Effect sensor and wherein said plastic lead frame includes at least one electrically conductive snap-together connector for linking at least part of said sensor to the at least one external power source.

6. The plastic lead frame and electrical component system of claim 1, wherein said integrated circuit is configured as a Vertical Cavity Surface Emitting Laser (VCSEL) sensor and wherein said plastic lead frame includes at least one electrically conductive snap-together connector for linking at least part of said sensor to the at least one external power source.

7. The plastic lead frame and electrical component system of claim 1, wherein said plastic lead frame includes a plurality of leads and at least one electrically conductive snap-together connector and wherein said leads operate as a linkage between said sensor and the at least one external electrical power source.

8. The plastic lead frame and electrical component system of claim 1, wherein said plastic lead frame is electrically connected to said integrated circuit by a conductive adhesive material and wherein said plastic lead frame device includes at least one electrically conductive snap-together connector.

9. The plastic lead frame and electrical component system of claim 1, wherein said plastic lead frame is a plastic-injected device and wherein said plastic lead frame includes at least one electrically conductive snap-together connector for linking at least part of said sensor to the at least one external power source.

10. The plastic lead frame and electrical component system of claim 1, wherein said plastic lead frame device is a plastic-injected device and wherein said integrated circuit is configured as an Hall Effect sensor and wherein said plastic lead frame device includes at least one electrically conductive snap-together connector for linking at least part of said sensor to the at least one external power source.

11. An electrical component system comprising:
an integrated circuit functioning as a sensor; and
a plastic-injected lead frame wherein said plastic lead frame includes at least one electrically conductive snap-together connector configured as an electrical linkage between said sensor and external electronic components including a power source.

12. The electrical component system of claim 11, wherein said integrated circuit is configured as a pressure sensor and wherein said plastic-injected lead frame includes at least one electrically conductive snap-together connector for linking at least part of said sensor to the external power source.

13. The electrical component system of claim 11, wherein said integrated circuit is configured as a Hall Effect sensor and wherein said plastic-injected lead frame includes at least one electrically conductive snap-together connector for linking at least part of said sensor to the external power source.

14. The electrical component system of claim 11, wherein said plastic lead frame is electrically connected to said integrated circuit by wire bonding and wherein said plastic lead frame device includes at least one electrically conductive snap-together connector.

15. A method of employing plastic lead frames to mount and electrically connect electrical devices, comprising
heating raw plastic materials in a granular form until said materials liquefy;
injecting the liquefied plastic into a pressurized mold in the shape of a customer-specified plastic lead frame including at least one electrically conductive snap-together connector;
cooling said liquefied plastic until said plastic lead frame is hardened and formed;
plating said plastic lead frame with a chemical substance;
projecting at least one circuit layout onto said plastic lead frame using known photolithographic techniques;
connecting said plastic lead frame to said electrical devices by snapping-together said plastic lead frame into a specified configuration; and
removing said plastic lead frame from said electrical devices by snapping-apart said plastic lead frame from a specified configuration, thus facilitating serviceability and/or replacement.

16. The method of claim 15 wherein said plastic lead frame comprises at least one integrated circuit functioning as a sensor and wherein said plastic lead frame includes at least one electrically conductive snap-together connector for linking at least part of said sensor to at least one external power source.

17. The method of claim 15 wherein said plastic lead frame comprises at least one integrated circuit configured as an automotive gear tooth sensor and wherein said plastic lead frame includes at least one electrically conductive snap-together connector for linking at least part of said sensor to at least one external power source.

18. The method of claim 15 wherein said plastic lead frame is configured as a Vertical Cavity Surface Emitting Laser (VCSEL) sensor and wherein said plastic lead frame includes at least one electrically conductive snap-together connector for linking at least part of said sensor to at least one external power source.

19. The method of claim 15 wherein said plastic lead frame is configured as a Hall Effect sensor and wherein said plastic lead frame includes at least one electrically conductive snap-together connector for linking at least part of said sensor to at least one external power source.

20. The method of claim 15 wherein the plastic materials used in the initial heating process comprise recycled plastic components.
